(19) United States
(12) Patent Application Publication
(10) Pub. No.: US 2024/0071905 A1
(43) Pub. Date: Feb. 29, 2024

(54) METHODS OF FORMING MICROELECTRONIC DEVICES, AND RELATED MICROELECTRONIC DEVICES, MEMORY DEVICES, AND ELECTRONIC SYSTEMS

(71) Applicant: Micron Technology, Inc., Boise, ID (US)

(72) Inventors: Martin J. Barclay, Middleton, ID (US); Mojtaba Asadirad, Boise, ID (US); Yiping Wang, Boise, ID (US); Matthew Holland, Victor, NY (US); Mohad Baboli, Boise, ID (US)

(21) Appl. No.: 17/898,107

(22) Filed: Aug. 29, 2022

(51) Int. Cl. H01L 23/522; H01L 21/768

(52) U.S. Cl. CPC H01L 23/5226; H01L 21/76831; H01L 21/76832; H01L 21/76877; H01L 27/11582

(57) ABSTRACT

A microelectronic device comprises a stack structure, a staircase structure, a first liner material, an etch stop structure, and conductive contact structures. The stack structure includes conductive structures and insulative structures arranged in tiers. The stack structure includes sidewalls horizontally bounding the staircase structure. The staircase structure has steps includes edges of tiers of the stack structure. The first liner material is on the steps and the sidewalls and includes horizontally extending portions on the steps and vertically extending portions on the sidewalls. The etch stop structure is on the horizontally extending portions of the first liner material, the vertically extending portions of the first liner material being free of the etch stop structure. The conductive contact structures extend through the etch stop structure and the first liner material and to the conductive structures. Memory devices, electronic systems, and methods of forming microelectronic devices are also described.

### TECHNICAL FIELD

The disclosure, in various embodiments, relates generally to the field of microelectronic device design and fabrication. More specifically, the disclosure relates to methods of forming microelectronic devices, and to related microelectronic devices, memory devices, and electronic systems.

### BACKGROUND

A continuing goal of the microelectronics industry has been to increase the memory density (e.g., the number of memory cells per memory die) of memory devices, such as non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes vertical memory strings extending through openings in one or more stack structures including tiers of conductive structures and dielectric materials. Each vertical memory string may include at least one select device coupled in series to a serial combination of vertically stacked memory cells. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

Vertical memory array architectures generally include electrical connections between the conductive structures of the tiers of the stack structure(s) of the memory device and access lines (e.g., word lines) so that the memory cells of the vertical memory array can be uniquely selected for writing, reading, or erasing operations. One method of forming such an electrical connection includes forming so-called “staircase” (or “stair step”) structures at edges (e.g., horizontal ends) of the tiers of the stack structure(s) of the memory device. The staircase structure includes individual “steps” defining contact regions of the conductive structures, upon which conductive contact structures can be positioned to provide electrical access to the conductive structures.

Unfortunately, as feature packing densities have increased and margins for formation errors have decreased, conventional methods of forming memory devices (e.g., NAND Flash memory devices) have resulted in undesirable damage that can diminish desired memory device performance, reliability, and durability. For example, conventional processes of forming conductive contact structures on the steps of a staircase structure within a stack structure may punch through conductive structures of the stack structure, resulting in undesirable current leaks and short circuits. Conventional methods of mitigating such punch through include forming dielectric pad structures (e.g., so called “mesa nitride” structures) on sacrificial insulative structures (e.g., dielectric nitride structures) at steps of a staircase structure within a preliminary stack structure prior to subjecting the preliminary stack structure to so called “replacement gate” or “gate last” processing to replace one or more portions of the sacrificial insulative structures with conductive structures and form the stack structure. During the replacement gate processing the dielectric pad structures are also replaced with conductive material to effectively increase thicknesses of portions of the conductive structures at the steps of the staircase structure and mitigate the aforementioned punch through during the subsequent formation of the conductive contact structures. However, the configurations of some staircase structures within a preliminary stack structure may result in undesirable defects (e.g., material inconsistencies, voiding) at the steps of the staircase structure.

### BRIEF DESCRIPTION OF THE DRAWINGS

FIGS. 1A-10 are simplified, partial longitudinal cross-sectional views illustrating a microelectronic device structure at different processing stages of a method of forming a microelectronic device, in accordance with embodiments of the disclosure;

FIGS. 11A-14B are simplified, partial longitudinal cross-sectional views illustrating a microelectronic device structure at different processing stages of a method of forming a microelectronic device, in accordance with embodiments of the disclosure;

FIG. 15 is a partial cutaway perspective view of a microelectronic device, in accordance with embodiments of the disclosure; and

FIG. 16 is a schematic block diagram illustrating an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Embodiments of the disclosure may be practiced in conjunction with conventional microelectronic device fabrication techniques employed in the industry. In addition, the description provided below does not form a complete process flow for manufacturing a microelectronic device (e.g., a memory device, such as 3D NAND Flash memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessary limited to memory functionality. Stated another way, and by way of non-limiting example only, the term “memory device” includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pa), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

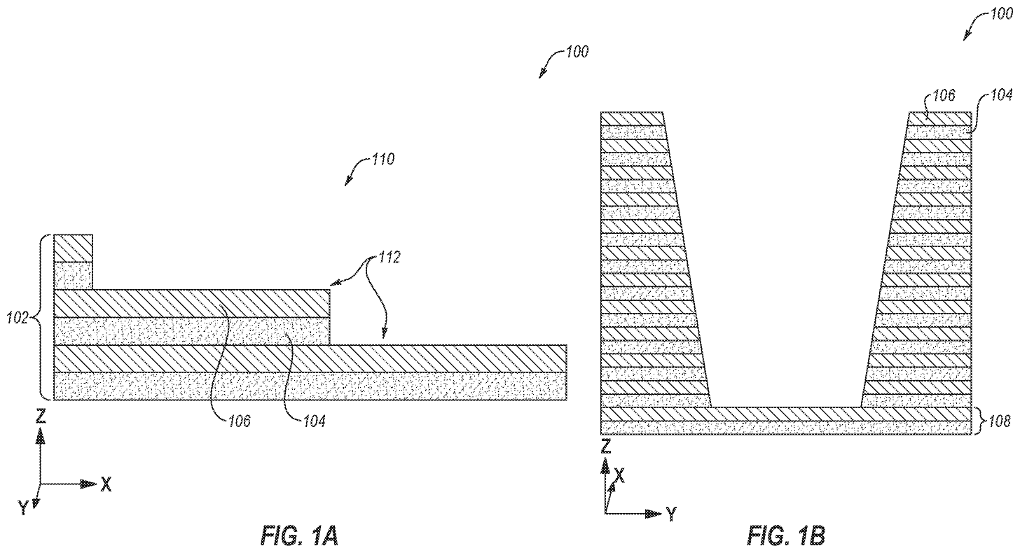

FIGS. 1A through 10 are simplified, longitudinal partial cross-sectional views illustrating a microelectronic device structure at different processing stages of a method of forming a microelectronic device (e.g., a memory device, such as a 3D NAND Flash memory device), in accordance with embodiments of the disclosure. With the description provided below, it will be readily apparent to one of ordinary skill in the art that the methods described herein may be used for forming various devices. In other words, the methods of the disclosure may be used whenever it is desired to form a microelectronic device.

Referring to FIGS. 1A and 1B, a microelectronic device structure 100 may be formed to include a preliminary stack structure 102. The preliminary stack structure 102 includes a vertically alternating (e.g., in the Z-direction) sequence of insulative material 104 and sacrificial material 106 arranged in tiers 108. Each of the tiers 108 of the preliminary stack structure 102 may include the insulative material 104 vertically neighboring the sacrificial material 106. The preliminary stack structure 102 may be formed to include any desired number of the tiers 108, such as greater than or equal to sixteen (16) tiers 108, greater than or equal to thirty-two (32) tiers 108, greater than or equal to sixty-four (64) tiers 108, greater than or equal to one hundred twenty-eight (128) tiers 108, or greater than or equal to two hundred fifty-six (256) tiers 108.

The insulative material 104 of the tiers 108 of the preliminary stack structure 102 may be formed of and include at least one dielectric material, such one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the insulative material 104 of the tiers 108 of the preliminary stack structure 102 is formed of and includes silicon dioxide (SiO₂). The insulative material 104 of each of the tiers 108 may be substantially the same (e.g., exhibit substantially the same material composition, material distribution, size, and shape) as the insulative material 104 of each other the tiers 108, or at least one of the insulative material 104 of at least one of the tiers 108 may be different (e.g., exhibit one or more of a different material composition, a different material distribution, a different size, and a different shape) than the insulative material 104 of at least one other of the tiers 108. In some embodiments, the insulative material 104 of each of the tiers 108 is substantially the same as the insulative material 104 of each other of the tiers 108.

The sacrificial material 106 of the tiers 108 of the preliminary stack structure 102 may be formed of and include at least one material (e.g., at least one dielectric material) that may be selectively removed relative to the insulative material 104 of the tiers 108 of the preliminary stack structure 102. The sacrificial material 106 may be selectively etchable relative to the insulative material 104 during common (e.g., collective, mutual) exposure to a first etchant, and the insulative material 104 may be selectively etchable to the sacrificial material 106 during common exposure to a second, different etchant. As used herein, a material is “selectively etchable” relative to another material if the material exhibits an etch rate that is at least about five times (5×) greater than the etch rate of another material, such as about ten times (10×) greater, about twenty times (20×) greater, or about forty times (40×) greater. A material composition of the sacrificial material 106 is different than a material composition of the insulative material 104. As a non-limiting example, the sacrificial material 106 of the tiers 108 of the preliminary stack structure 102 may comprise an additional dielectric material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the sacrificial material 106 of the tiers 108 of the preliminary stack structure 102 is formed of and includes a dielectric nitride material, such as SiN_{y} (e.g., Si₃N₄). The sacrificial material 106 of each of the tiers 108 may be substantially the same (e.g., exhibit substantially the same material composition, material distribution, size, and shape) as the sacrificial material 106 of each other the tiers 108, or at least one of the sacrificial material 106 of at least one of the tiers 108 may be different (e.g., exhibit one or more of a different material composition, a different material distribution, a different size, and a different shape) than the sacrificial material 106 of at least one other of the tiers 108. In some embodiments, the sacrificial material 106 of each of the tiers 108 is substantially the same as the sacrificial material 106 of each other of the tiers 108.

With continued reference to FIGS. 1A and 1B, the microelectronic device structure 100 may further include at least one staircase structure 110 including steps 112 (e.g., contact regions) defined by edges (e.g., horizontal ends) of the tiers 108. The staircase structure 110 may include a desired quantity of the steps 112. As shown in FIG. 1A, in some embodiments, the steps 112 of the staircase structure 110 are arranged in order, such that steps 112 horizontally neighboring one another in the X-direction correspond to tiers 108 of the preliminary stack structure 102 vertically neighboring one another in the Z-direction. In additional embodiments, the steps 112 of the staircase structure 110 are arranged out of order, such that at least some steps 112 of the staircase structure 110 horizontally neighboring one another in the X-direction correspond to tiers 108 of preliminary stack structure 102 not vertically neighboring one another in the Z-direction.

The preliminary stack structure 102 may include a desired quantity and distribution (e.g., spacing and arrangement) of staircase structures 110. The preliminary stack structure 102 may include a single (e.g., only one) staircase structure 110, or may include multiple (e.g., more than one) staircase structures 110. If the preliminary stack structure 102 includes multiple staircase structures 110, each of the staircase structures 110 may be positioned at a different vertical location (e.g., in the Z-direction) within the preliminary stack structure 102, or at least one of the staircase structures 110 may be positioned at substantially the same vertical location (e.g., in the Z-direction) within the preliminary stack structure 102 as at least one other of the staircase structures 110. If multiple staircase structures 110 are positioned at substantially the same vertical location (e.g., in the Z-direction) within the preliminary stack structure 102, the staircase structures 110 may be horizontally positioned in series with one another, in parallel with one another, or a combination thereof. If multiple staircase structures 110 at substantially the same vertical location (e.g., in the Z-direction) (if any) within the preliminary stack structure 102 are horizontally positioned in series with one another, each of the staircase structures 110 may exhibit a positive slope, each of the staircase structures 110 may exhibit a negative slope, or at least one of the staircase structures 110 may exhibit a positive slope and at least one other of the staircase structures 110 may exhibit a negative slope. For example, the preliminary stack structure 102 may include one or more stadium structures individually comprising a first staircase structure 110 having positive slope, and a second staircase structure 110 horizontally neighboring and in series with the first staircase structure 110 and having negative slope.

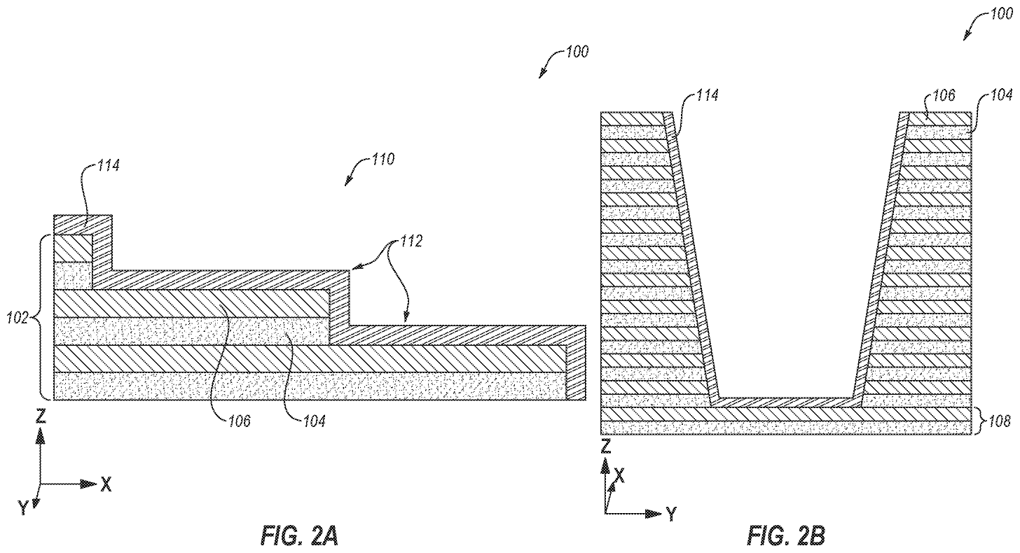

Referring next to FIGS. 2A and 2B, a first liner material 114 may be formed on or over exposed surfaces of the preliminary stack structure 102. As shown in FIG. 2B, the first liner material 114 may be formed on or over exposed surfaces (e.g., exposed horizontal surfaces, exposed vertical surfaces) of the preliminary stack structure 102 at least partially defining the staircase structure 110. Optionally, the first liner material 114 may also be formed on or over additional exposed surfaces (e.g., exposed horizontally extending surfaces, exposed vertically extending surfaces) of the preliminary stack structure 102 outside of the boundaries (e.g., horizontal boundaries, vertical boundaries) of the staircase structure 110. The first liner material 114 may at least partially (e.g., substantially) conform to a topography defined by the surfaces (e.g., horizontal surfaces, vertical surfaces) upon which the first liner material 114 is formed.

The first liner material 114 may be formed of and include at least one material having different etch selectivity than the sacrificial material 106 of the preliminary stack structure 102. Following additional processing, portions of the first liner material 114 may be employed to protect portions of a stack structure formed from the preliminary stack structure 102 during subsequent processing acts (e.g., subsequent material removal acts, such as subsequent etching acts), as described in further detail below. As a non-limiting example, the first liner material 114 may comprise at least one oxygen-containing dielectric material, such as a one or more of a dielectric oxide material (e.g., SiOₓ, phosphosilicate glass, borosilicate glass, borophosphosilicate glass, fluorosilicate glass, AlOₓ, HfOₓ, NbOₓ, TiOₓ), a dielectric oxynitride material (e.g., SiOₓN_{y}), and a dielectric carboxynitride material (e.g., SiOₓC_{z}N_{y}). In some embodiments, the first liner material 114 is formed of and includes SiOₓ (e.g., SiO₂). In additional embodiments, the first liner material 114 is formed of and includes an oxide of a metal material. The first liner material 114 may be substantially homogeneous, or the first liner material 114 may be heterogeneous.

The first liner material 114 may be formed to exhibit a desirable thickness less than the horizontal dimension (e.g., width) in the X-direction of the individual steps 112 of the staircase structure 110. The thickness of the first liner material 114 may, for example, be less than or equal to half of a width in the X-direction of a horizontally smallest step 112 of the staircase structure 110. By way of non-limiting example, the thickness of the first liner material 114 may be within a range of from about 5 nanometers (nm) to about 1000 nm. In some embodiments, a thickness of the first liner material 114 is less than a thickness of the insulative material 104 of an individual tier 108 of the preliminary stack structure 102.

The first liner material 114 may be formed using conventional processes (e.g., conventional conformal deposition processes, such as one or more of a conventional conformal CVD process and a conventional ALD process; conventional oxidation processes) and conventional processing equipment, which are not described in detail herein.

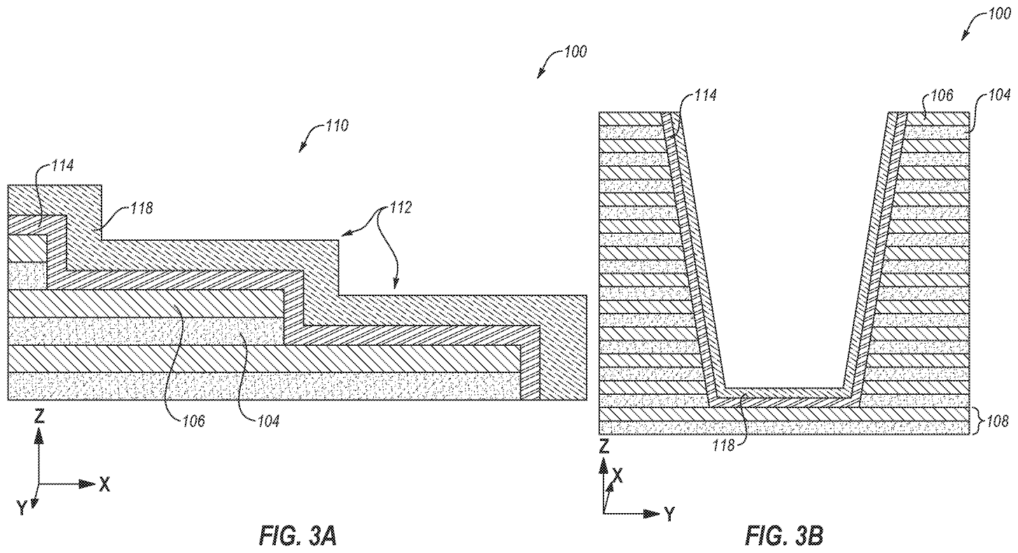

Referring next to FIGS. 3A and 3B, a second liner material 118 may be formed on or over the first liner material 114. The second liner material 118 may be formed on surfaces of the first liner material 114. The second liner material 118 may be formed to cover exposed horizontally extending surfaces and exposed vertically extending surfaces of the first liner material 114 of the microelectronic device structure 100 inside of and outside of boundaries (e.g., horizontal boundaries, vertical boundaries) of the staircase structure 110. The second liner material 118 may at least partially (e.g., substantially) conform to a topography defined by the surfaces (e.g., horizontal surfaces, vertical surfaces) upon which the second liner material 118 is formed.

The second liner material 118 may be formed of and include at least one material having different etch selectivity than the first liner material 114. The second liner material 118 may also have, or may subsequently be further processed (e.g., doped) to have, different etch selectivity than the sacrificial material 106 of the preliminary stack structure 102. Following additional processing, portions of the second liner material 118 may be employed to protect portions of the stack structure formed from the preliminary stack structure 102 during subsequent processing acts (e.g., subsequent material removal acts, such as subsequent etching acts), as described in further detail below. The second liner material 118 may be formed of and include one or more of at least one insulative material (e.g., a dielectric oxide material, a dielectric nitride material, a dielectric oxynitride material, a dielectric carboxynitride material). In some embodiments, the second liner material 118 is formed of and includes polycrystalline silicon. In additional embodiments, the second liner material 118 is formed of and includes a dielectric oxide material (e.g., SiOₓ, such as SiO₂). In further embodiments, the second liner material 118 is formed of and includes a dielectric nitride material (e.g., SiN_{y}, such as Si₃N₄). The second liner material 118 may be substantially homogeneous, or the second liner material 118 may be heterogeneous.

The second liner material 118 may be formed to exhibit a desirable thickness in each of the Z-direction and the X-direction. A thickness of some portions of the second liner material 118 in the Z-direction may, for example, be between about 35 nm and about 80 nm. As a non-limiting example, some portions of the second liner material 118 may have a thickness in the Z-direction of about 50 nm.

The second liner material 118 may be formed using one or more conventional conformal deposition processes, such as one or more of a conventional conformal CVD process and a conventional ALD process.

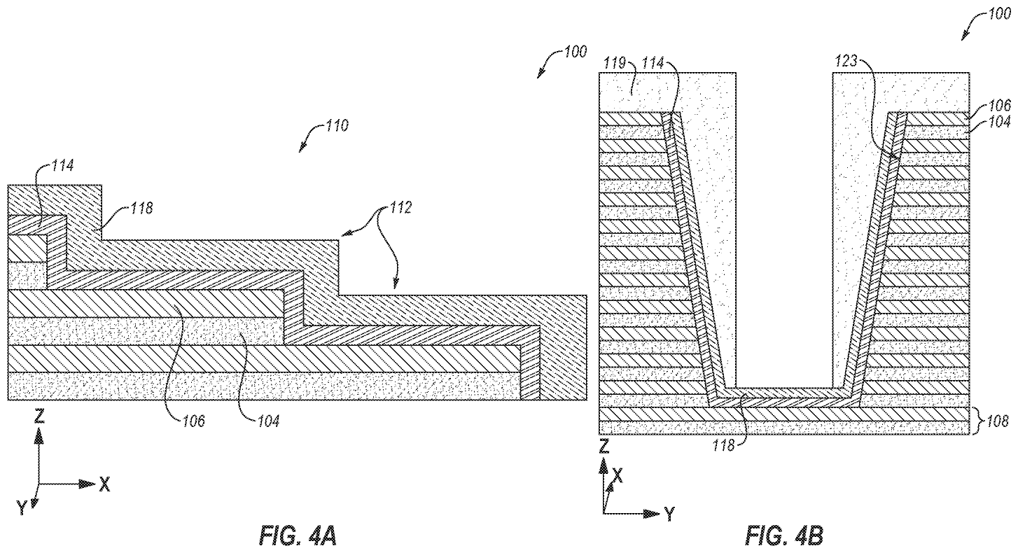

Referring to FIGS. 4A and 4B, a resist patterning material 119 may be formed on or over the second liner material 118 and exposed surfaces of the preliminary stack structure 102. Furthermore, the resist patterning material 119 may be patterned via one or more conventional methods to expose horizontally extending portions of the second liner material 118 above steps 112 of the at least one staircase structure 110 of the microelectronic device structure 100 while covering vertically extending portions of the second liner material 118 on sidewalls 123 of the preliminary stack structure 102 horizontally bounding the at least one staircase structure 110 (e.g., vertical surfaces facing and on lateral sides of the at least one staircase structure 110 in the Y-direction). In some embodiments, the resist patterning material 119 is formed and patterned to cover at least a portion of the horizontally extending portions of the second liner material 118 (e.g., a portion of the horizontally extending portions of the second liner material 118 proximate the vertically extending portions of the second liner material 118 on sidewalls 123 of the preliminary stack structure 102).

As depicted in FIGS. 4A and 4B, in some embodiments, the resist patterning material 119 is formed and patterned to expose a strip of the second liner material 118 extending in the X-direction (e.g., in a direction in which the staircase structure 110 ascends and/or descends) over multiple steps 112 of the staircase structure 110. For instance, the exposed portion of the second liner material 118 may span multiple steps 112 of the staircase structure 110 in the X-direction. In additional embodiments, the resist patterning material 119 is formed and patterned to expose multiple discrete portions of the second liner material 118, each discrete exposed portion of the second liner material 118 being above a respective step 112 of the staircase structure 110.

In some embodiments, the resist patterning material 119 includes a light-sensitive material usable in processes, such as photolithography. For example, the resist patterning material 119 may include one or more of a photopolymeric photoresist material, a photodecomposing photoresist material, and a photocrosslinking photoresist material.

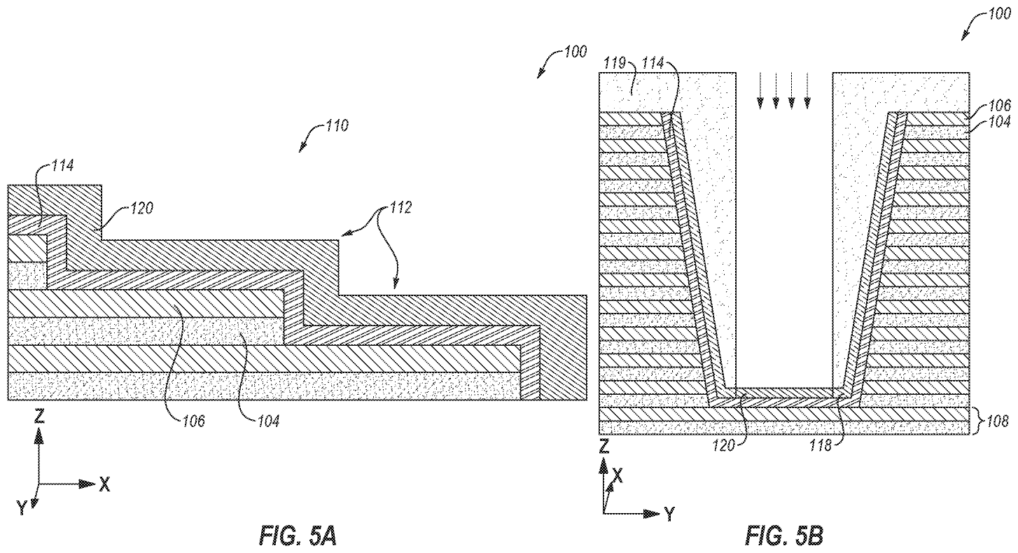

Referring next to FIGS. 5A and 5B, horizontal surfaces of the exposed portion of second liner material 118 may be doped (e.g., impregnated, implanted) with one or more dopants (e.g., chemical species) to form a doped second liner material 120. Furthermore, in some embodiments, only the exposed portions of the second liner material 118 are doped, and covered portions of the second liner material 118 remain undoped (e.g., free of the one or more dopants), as depicted in FIGS. 5A and 5B. For example, vertically extending portions of the second liner material 118 on sidewalls 123 of the preliminary stack structure 102 horizontally bounding the at least one staircase structure 110 (e.g., vertical surfaces facing and on lateral sides of the at least one staircase structure 110 in the Y-direction) and covered by the resist patterning material 119 may remain undoped.

A vertical thickness (e.g., in the Z-direction) of the dopant(s) (e.g., a vertical depth of the doped second liner material 120 may be at least substantially equal to a vertical thickness of the second liner material 118. In other words, at least substantially an entire vertical thickness of the exposed portion of the second liner material 118 may be doped with the dopant.

The dopant(s) of the doped second liner material 120 may comprise material(s) promoting or facilitating selective removal of undoped portions of the second liner material 118 relative to the doped second liner material 120 and/or the first liner material 114. Depending on a material composition of the second liner material 118, the dopant(s) may, for example, comprise one or more of carbon (C), boron (B), at least one N-type dopant (e.g., one or more of phosphorus (P), arsenic (Ar), antimony (Sb), and bismuth (Bi)), at least one other P-type dopant (e.g., a P-type dopant other than B, such as aluminum (Al) and/or gallium (Ga)), nitrogen (N), oxygen (O), fluorine (F), chlorine (Cl), bromine (Br), hydrogen (H), deuterium (²H), helium (He), neon (Ne), and argon (Ar). In some embodiments, such as some embodiments wherein the second liner material 118 comprises a dielectric nitride material (e.g., SiN_{y}), the dopant comprises carbon (C). In embodiments where the second liner material 118 comprises one or more of polycrystalline silicon or a dielectric oxide material (e.g., SiOₓ), the dopant may comprise boron (B).

The doped second liner material 120 may exhibit a substantially homogeneous distribution of dopant(s) within the material thereof, or may exhibit a heterogeneous distribution of dopant(s) within the material thereof. In some embodiments, the doped second liner material 120 exhibits a substantially homogeneous distribution of dopant(s) within the material thereof, such that the doped second liner material 120 exhibits a substantially uniform (e.g., even, non-variable) distribution of the dopant(s) within the material thereof. For example, amounts (e.g., atomic concentrations) of the dopant(s) included in the doped second liner material 120 may not substantially vary throughout the vertical dimensions (e.g., in the Z-direction) of the doped second liner material 120. In additional embodiments, the doped second liner material 120 exhibits a substantially heterogeneous distribution of dopant(s) within the material thereof, such that the doped second liner material 120 exhibits a substantially non-uniform (e.g., non-even, variable) distribution of the dopant(s) within the material thereof. For example, amounts (e.g., atomic concentrations) of the dopant(s) included in the doped second liner material 120 may vary (e.g., increase, decrease) throughout a vertical dimension (e.g., in the Z-direction) of the doped second liner material 120.

The second liner material 118 may be doped with at least one dopant to form the doped second liner material 120 using conventional processes (e.g., conventional implantation processes, conventional diffusion processes), which are not described in detail herein. As a non-limiting example, one or more carbon-containing species (e.g., carbon atoms, carbon-containing molecules, carbon ions, carbon-containing ions) may be implanted into the second liner material 118 to form the doped second liner material 120. As another non-limiting example, one or more boron-containing species (e.g., boron atoms, boron-containing molecules, boron ions, boron-containing ions) may be implanted into the second liner material 118 to form the doped second liner material 120. In some embodiments, following dopant implantation, an amount of dopant within at least the doped second liner material 120 is within a range of from about 1.0×10¹⁷ dopant atoms per cubic centimeter (cm³) to about 1.0×10²³ dopant atoms/cm³.

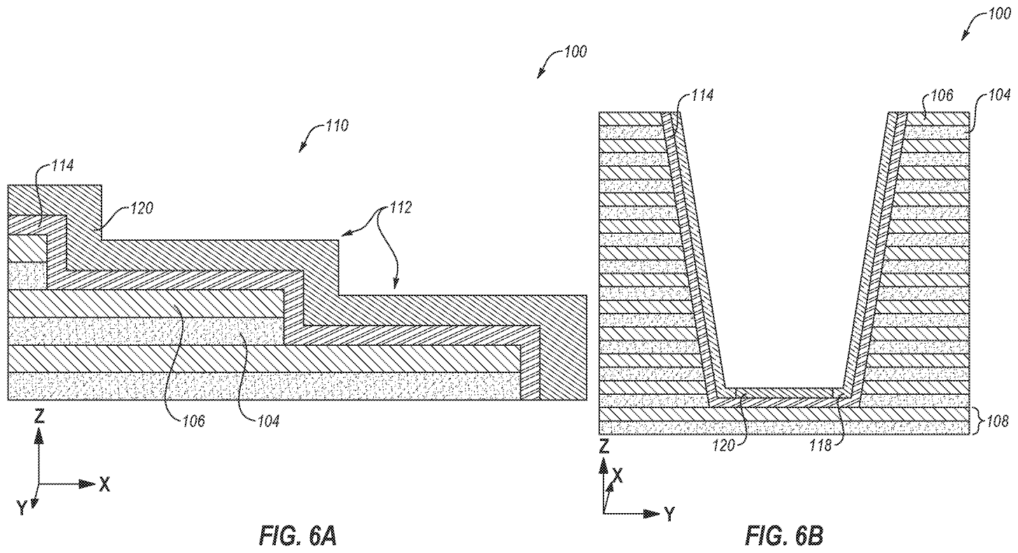

Referring next to FIGS. 6A and 6B, the resist patterning material 119 disposed over the preliminary stack structure 102 may be substantially removed. The resist patterning material 119 may be removed via conventional removal processes. For example, the removal processes may include one or more of dry etching, wet etching, or vapor etching. The dry etching may include one or more of RIE, deep RIE, plasma etching, reactive ion beam etching, or chemically assisted ion beam etching.

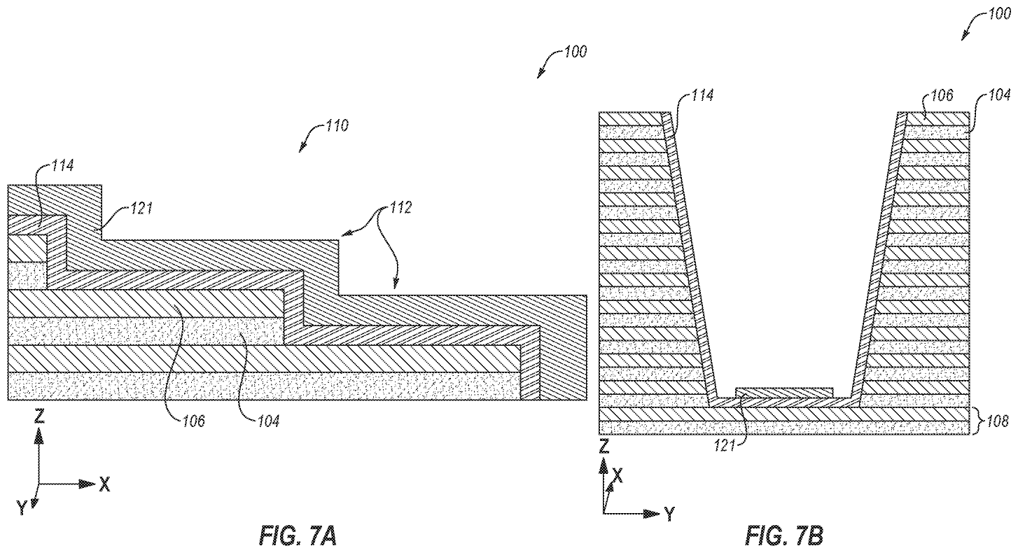

Referring next to FIGS. 7A and 7B, the dopant-free portions of the second liner material 118 may be substantially, selectively removed. For example, the dopant-free portions of the second liner material 118 disposed over the sidewalls 123 of the preliminary stack structure 102 horizontally bounding the steps 112 of the at least one staircase structure 110 and extending substantially vertically up from the first liner material 114 may be substantially removed to expose vertically and/or substantially vertically extending surfaces of the first liner material 114.

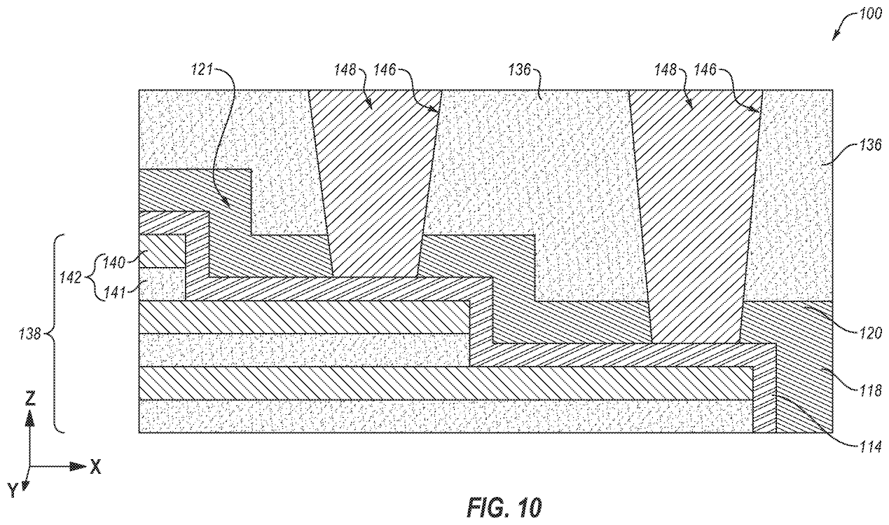

As shown in FIG. 7B, selective removal of the dopant-free portions of the second liner material 118 disposed on the first liner material 114 disposed on the sidewalls 123 of the preliminary stack structure 102 horizontally bounding the at least one staircase structure 110 may define an etch stop structure 121 with the doped second liner material 120. For example, selective removal of the dopant-free portions of the second liner material 118 disposed on vertically extending surfaces of the first liner material 114 disposed on the sidewalls 123 of the preliminary stack structure 102 horizontally bounding the at least one staircase structure 110 may result in the doped second liner material 120 disposed on horizontal surfaces of the first liner material 114 remaining and defining the etch stop structure 121. As a result, the portions of the first liner material 114 disposed on the sidewalls 123 of the preliminary stack structure 102 may be substantially free of the second liner material 118. As is discussed in greater detail below, removing the dopant-free portions of the second liner material 118 from the first liner material 114 disposed on the sidewalls 123 of the preliminary stack structure 102 horizontally bounding the at least one staircase structure 110 may reduce bending of latter formed contact structures 148 (FIG. 10).

In some embodiments, the etch stop structure 121 is spaced apart from portions of the first liner material 114 disposed on (e.g., lining) the sidewalls 123 of the preliminary stack structure 102 by at least some distance in the Y-direction. In additional embodiments, the etch stop structure 121 extends and contacts the portions of the first liner material 114 disposed on (e.g., lining) the sidewalls 123 of the preliminary stack structure 102.

Referring still to FIGS. 7A and 7B, the dopant-free portions of the second liner material 118 disposed on the sidewalls 123 of the preliminary stack structure 102 horizontally bounding the at least one staircase structure 110 may be removed by treating the second liner material 118 with at least one etchant (e.g., wet etchant). By way of non-limiting example, depending on the material composition of the second liner material 118, the etchant may comprise one or more of tetramethylammonium hydroxide (TMAH), hydrofluoric acid (HF), a buffered oxide etchant (BOE), or nitric acid (HNO₃). In additional embodiments, the material removal process includes treating the microelectronic device structure 100 with a solution including water and HF at a ratio within a range of from about 500:1 to about 100:1. The second liner material 118 may be exposed to the etchant using conventional processes (e.g., a spin-coating process, a spray-coating process, an immersion-coating process, a vapor-coating process, a soaking process, combinations thereof) and conventional processing equipment, which are not described in detail herein.

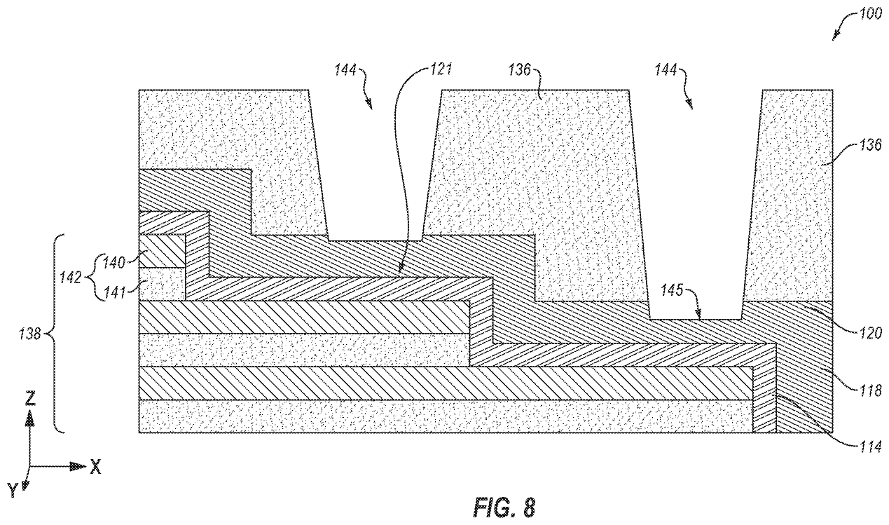

Referring next to FIG. 8, an isolation material 136 may be formed on or over the preliminary stack structure 102, the staircase structure 110, and the etch stop structure 121 of the doped second liner material 120. As shown in FIG. 8, the isolation material 136 may substantially extend across and cover surfaces of the etch stop structure 121 of the doped second liner material 120 and the steps 112 of the staircase structure 110. The isolation material 136 may be formed to have a substantially planar upper boundary, and a non-planar lower boundary complementary (e.g., substantially mirroring) to the topography thereunder.

The isolation material 136 may be formed of and include at least one dielectric material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). A material composition of the isolation material 136 is different than a material composition of the sacrificial material 106 of the tiers 108 of the preliminary stack structure 102. The material composition of the isolation material 136 may be substantially the same as or may be different than a material composition of the insulative material 104 of the tiers 108 of the preliminary stack structure 102. In some embodiments, the isolation material 136 is formed of and includes SiO₂. The isolation material 136 may be substantially homogeneous, or may be heterogeneous.

Referring still to FIG. 8, following the formation of the isolation material 136, the microelectronic device structure 100 may be subjected to replacement gate processing to at least partially replace the sacrificial material 106 (FIG. 7A) of the tiers 108 (FIG. 7A) of the preliminary stack structure 102 (FIG. 7A) with conductive structures 140 and form a stack structure 138. Thereafter, portions of the isolation material 136 may be removed, to form initial contact openings 144 vertically extending through the isolation material 136 and to or through the etch stop structure 121 of the doped second liner material 120.

As shown in FIG. 8, the stack structure 138 is formed to include a vertically alternating (e.g., in the Z-direction) sequence of the conductive structures 140 and insulative structures 141 arranged in tiers 142. Each of the tiers 142 of the stack structure 138 includes at least one of the conductive structures 140 vertically neighboring at least one of the insulative structures 141. The conductive structures 140 may be formed of and include at least one conductive material, such as one or more of a metal, an alloy, a conductive metal oxide, a conductive metal nitride, a conductive metal silicide, and a conductively doped semiconductor material. In some embodiments, the conductive structures 140 are formed of and include W. The insulative structures 141 may comprise portions of the insulative material 104 (FIG. 7A) of the tiers 108 (FIG. 7A) of the preliminary stack structure 102 (FIG. 7A) remaining (e.g., unremoved) following the replacement gate processing. In some embodiments, the insulative structures 141 are formed of and include SiO₂.

During replace gate processing, the preliminary stack structure 102 (FIG. 7A) may be subjected to a material removal process to selectively remove (e.g., selectively exhume) at least a portion (e.g., all, less than all) of the sacrificial material 106 (FIG. 7A) of the tiers 108 (FIG. 7A) of the preliminary stack structure 102 (FIG. 7A) relative to the insulative material 104 (FIG. 7A) of the tiers 108 (FIG. 7A). For example, slots (e.g., slits, openings, trenches) may be formed to vertically extend (e.g., in the Z-direction) through the preliminary stack structure 102 (FIG. 7A), and then portions of the sacrificial material 106 (FIG. 7A) may be selectively removed through the slots using one or more etchants. Thereafter, open volumes (e.g., void spaces) formed by the removed portions of the sacrificial material 106 (FIG. 7A) may be filled with conductive material (e.g., W) to form the conductive structures 140.

Still referring to FIG. 8, the initial contact openings 144 may be formed to vertically extend through the isolation material 136 and expose (e.g., uncover) portions of the second liner material 118 (e.g., the etch stop structure 121 of the doped second liner material 120). The initial contact openings 144 may vertically terminate at a bottom surface 145 at or within the etch stop structure 121 of the doped second liner material 120. In some embodiments, one or more of the initial contact openings 144 are formed to terminate at or within the etch stop structure 121 of the doped second liner material 120. The etch stop structure 121 of the doped second liner material 120 may serve as so-called “etch stop” structures to mitigate (e.g., prevent) undesirable damage (e.g., over-etching damage, punch-through damage) to the tiers 142 of the stack structure 138 during the formation of the initial contact openings 144.

Each initial contact opening 144 may individually be formed at desired a horizontal position (e.g., in the X-direction and the Y-direction) within a horizontal area of the etch stop structure 121 of the doped second liner material 120. The initial contact opening 144 may be positioned within a horizontal area of a step 112 of the staircase structure 110 in physical contact with the etch stop structure 121 of the doped second liner material 120. In some embodiments, within a horizontal area of the staircase structure 110, the initial contact openings 144 are substantially horizontally aligned with one another in the Y-direction. In additional embodiments, within the horizontal area of the staircase structure 110, at least some of the initial contact openings 144 are horizontally offset in the Y-direction from at least some other of the initial contact openings 144.

The initial contact openings 144 may each individually be formed to exhibit a desired horizontal cross-sectional shape. In some embodiments, each of the initial contact openings 144 is formed to exhibit a substantially circular horizontal cross-sectional shape. In additional embodiments, one or more (e.g., each) of the initial contact openings 144 is formed to exhibit a non-circular cross-sectional shape, such as one more of an oblong cross-sectional shape, an elliptical cross-sectional shape, a square cross-sectional shape, a rectangular cross-sectional shape, a tear drop cross-sectional shape, a semicircular cross-sectional shape, a tombstone cross-sectional shape, a crescent cross-sectional shape, a triangular cross-sectional shape, a kite cross-sectional shape, and an irregular cross-sectional shape. In addition, each of the initial contact openings 144 may be formed to exhibit substantially the same horizontal cross-sectional dimensions (e.g., substantially the same horizontal diameter), or at least one of the initial contact openings 144 may be formed to exhibit one or more different horizontal cross-sectional dimensions (e.g., a different horizontal diameter) than at least one other of the initial contact openings 144. In some embodiments, all of the initial contact openings 144 are formed to exhibit substantially the same horizontal cross-sectional dimensions.

The initial contact openings 144 may be formed using conventional process (e.g., conventional material removal processes, such as conventional etching processes) and conventional processing equipment, which are not described in detail herein. As a non-limiting example, the initial contact openings 144 may be formed using anisotropic dry etching, such as one or more of RIE, deep RIE, plasma etching, reactive ion beam etching, and chemically assisted ion beam etching.

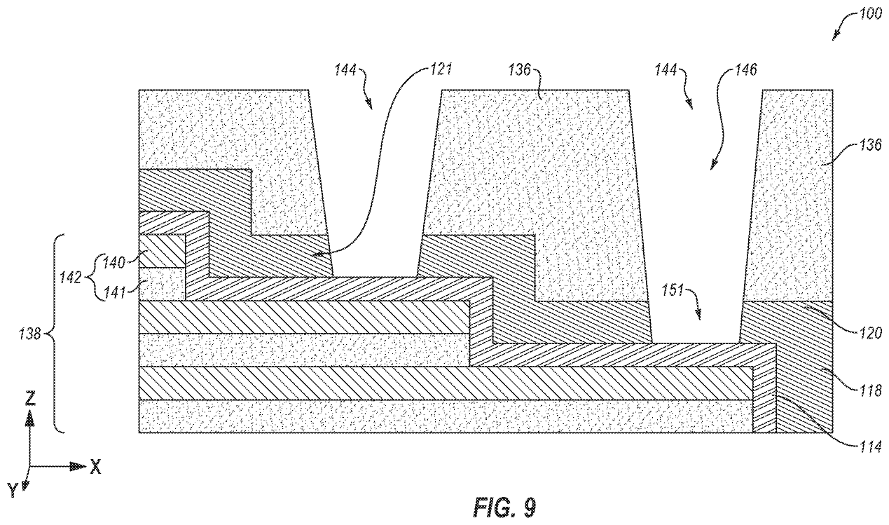

Referring next to FIG. 9, for each initial contact opening 144, any remaining portion of the doped second liner material 120 within horizontal areas of the initial contact opening 144 and a portion of the first liner material 114 within horizontal areas of the initial contact opening 144 may be removed to form an additional opening 151 and to expose a portion of the conductive structure 140 of an individual tier 142 of the stack structure 138 at an individual step 112 of the staircase structure 110 within the stack structure 138. The additional openings 151 may be formed by subjecting the microelectronic device structure 100 to an additional material removal process different than the material removal process employed to form the initial contact openings 144. As a non-limiting example, the additional openings 151 may be formed by subjecting any remaining portions of the doped second liner material 120 and portions of the first liner material 114 within horizontal areas of the initial contact openings 144 to a so-called “punch through” etch (e.g., a dry punch). The combination of the initial contact openings 144 and the additional openings 151 may form contact openings 146.

The width of each contact opening 146 in the Y-direction may be smaller than the width of the doped second liner material 120 (i.e., etch stop structure 121) in the Y-direction. Furthermore, at least where the contact openings 146 horizontally align with the doped second liner material 120 (i.e., etch stop structure 121), the horizontal areas of the contact openings 146 may be smaller in every horizontal direction than the horizontal areas spanned by the doped second liner material 120 (i.e., etch stop structure 121). Accordingly, each contact opening 146 may be surrounded in every horizontal direction (e.g., ringed) by the doped second liner material 120 (i.e., etch stop structure 121) where the contact opening 146 is aligned horizontally with the doped second liner material 120 (i.e., etch stop structure 121).

Referring next to FIG. 10, contact structures 148 may be formed within the contact openings 146. The contact structures 148 may be substantially confined within boundaries (e.g., horizontal boundaries, vertical boundaries) of the contact openings 146, and may substantially fill the contact openings 146. Each contact structure 148 may have a geometric configuration (e.g., shape, dimensions) corresponding to (e.g., substantially the same as) a geometric configuration of the contact opening 146 filled with the contact structure 148. As shown in FIG. 10, each contact structure 148 may have an uppermost vertical boundary (e.g., an uppermost surface) substantially coplanar with an uppermost vertical boundary (e.g., an uppermost surface) of the isolation material 136, and a lowermost vertical boundary (e.g., a lowermost surface) vertically adjacent an uppermost vertical boundary (e.g., an uppermost surface) of the conductive structure 140 of an individual tier 142 of the stack structure 138. In additional embodiments, one or more (e.g., each) of the contact structures 148 may have an uppermost vertical boundary offset from (e.g., vertically over, vertically under) an uppermost vertical boundary (e.g., an uppermost surface) of the isolation material 136. Each contact structure 148 may individually contact (e.g., physically contact, electrically contact) the conductive structure 140 of the individual tier 142 of the stack structure 138 at an individual step 112 of an individual staircase structure 110 of the stack structure 138.

The width of each contact structure 148 in the Y-direction may be smaller than the width of the doped second liner material 120 (i.e., etch stop structure 121) in the Y-direction. Furthermore, at least where the contact structures 148 horizontally align with the doped second liner material 120 (i.e., etch stop structure 121), the horizontal areas of the contact structure 148 (e.g., horizontal cross-sectional area) may be smaller in every horizontal direction than the horizontal areas spanned by the doped second liner material 120 (i.e., etch stop structure 121). Accordingly, each contact structure 148 may be surrounded in every horizontal direction (e.g., ringed) by the doped second liner material 120 (i.e., etch stop structure 121) where the contact structure 148 is aligned horizontally with the doped second liner material 120 (i.e., etch stop structure 121).

The contact structures 148 may be formed of and include conductive material. As a non-limiting example, the contact structures 148 may be formed of and include one or more of at least one metal, at least one alloy, and at least one conductive metal-containing material (e.g., a conductive metal nitride, a conductive metal silicide, a conductive metal carbide, a conductive metal oxide). A material composition of the contact structures 148 may be substantially the same as a material composition of the conductive structures 140 of the tiers 142 of the stack structure 138, or the material composition of the contact structures 148 may be different than the material composition of the conductive structures 140 of the tiers 142 of the stack structure 138. In some embodiments, the contact structures 148 are individually formed of and include W. The contact structures 148 may individually be homogeneous, or the contact structures 148 may individually be heterogeneous.

The contact structures 148 may be formed by forming (e.g., non-conformably depositing, such as through one or more of a PVD process and a non-conformal CVD process) conductive material inside and outside of the contact openings 146 (FIG. 9), and then removing (e.g., through an abrasive planarization process, such as a CMP process) portions of the conductive material overlying an uppermost vertical boundary (e.g., an uppermost surface) of the isolation material 136.

Referring to FIGS. 1A-10 together, the methods and structures described herein may be advantageous over conventional methods of forming microelectronic devices and conventional structures. For example, as noted above, the second liner material 118 and the horizontally extending portions 122 of the doped second liner material 120 (e.g., the liner structure 119) may serve as so-called “etch stop” structures to mitigate (e.g., prevent) undesirable damage (e.g., over-etching damage, punch-through damage) to the tiers 142 of the stack structure 138 during the formation of the initial contact openings 144.

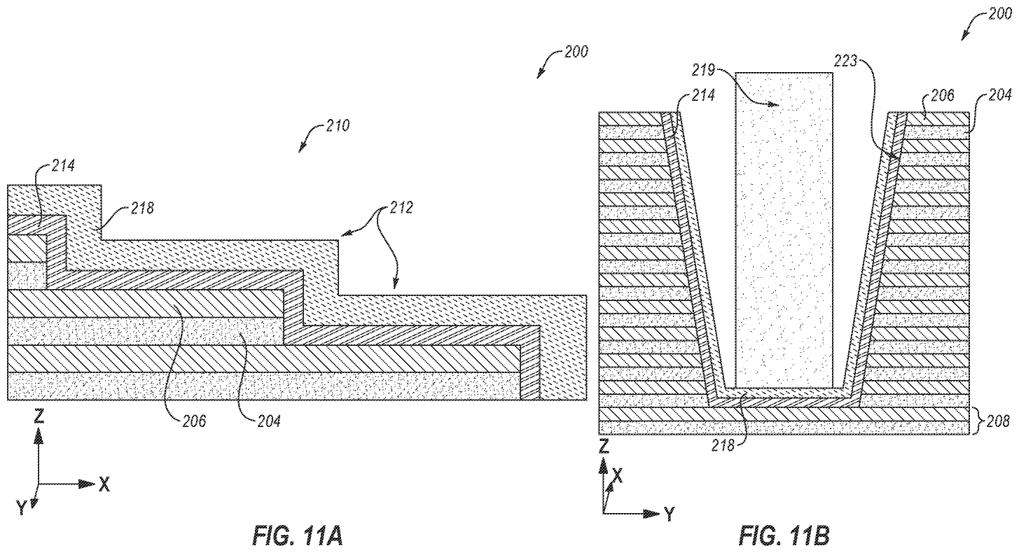

FIGS. 11A through 14B are simplified, longitudinal partial cross-sectional views illustrating a microelectronic device structure at different processing stages of a method of forming a microelectronic device (e.g., a memory device, such as a 3D NAND Flash memory device), in accordance with additional embodiments of the disclosure. With the description provided below, it will be readily apparent to one of ordinary skill in the art that the methods described herein may be used for forming various devices. In other words, the methods of the disclosure may be used whenever it is desired to form a microelectronic device. To avoid repetition, not all features (e.g., structures, materials, regions, devices) shown in FIGS. 11A through 14B are described in detail herein. Rather, unless described otherwise below, in FIGS. 11A through 14B, a feature designated by a reference numeral that is a 100 increment of the reference numeral of a feature previously described with reference to the microelectronic device structure 100 (FIGS. 1A through 10) will be understood to be substantially similar to the previously described feature.

Referring to FIGS. 11A and 11B, a microelectronic device structure 200 may include a preliminary stack structure 202 similar to or the same as the preliminary stack structure 102 described above in regard to FIGS. 1A-10. Likewise, the preliminary stack structure 202 includes a vertically alternating (e.g., in the Z-direction) sequence of insulative material 204 and sacrificial material 206 arranged in tiers 208. Moreover, like the microelectronic device structure 100 described above in regard to FIGS. 1A-10, the microelectronic device structure 200 includes first and second liner materials 214, 218 formed on or over exposed surfaces of the preliminary stack structure 102. The first and second liner materials 214, 218 may include any of the materials described above in regard to FIGS. 1A-10.

Referring still to FIGS. 11A and 11B, a resist patterning material 219 may be formed on or over the second liner material 218 and exposed surfaces of the preliminary stack structure 202. Furthermore, the resist patterning material 219 may be patterned via one or more conventional methods to expose vertically extending portions of the second liner material 218 disposed on the first liner material 214 disposed over (e.g., lining) sidewalls 223 of the preliminary stack structure 202 horizontally bounding the at least one staircase structure 210 (e.g., vertical surfaces facing and on lateral sides of the at least one staircase structure 210 in the Y-direction) while covering a horizontally extending portion of the second liner material 218 above steps 212 of the at least one staircase structure 210 of the microelectronic device structure 200. In some embodiments, the resist patterning material 219 is formed and patterned to cover at least substantially an entirety of the horizontally extending portion of the second liner material 218 over the steps 212 of the at least one staircase structure 210. Furthermore, the resist patterning material 219 may be formed and patterned to expose at least substantially an entirety of the vertically extending portions of the second liner material 218 on the sidewalls 223 of the preliminary stack structure 202.

As depicted in FIGS. 11A and 11B, in some embodiments, the resist patterning material 219 is formed and patterned to cover a strip of the second liner material 218 extending in the X-direction (e.g., in a direction in which the staircase structure 210 ascends and/or descends) over multiple steps 212 of the staircase structure 210. For instance, the covered portion of the second liner material 218 may span multiple steps 212 of the staircase structure 210 in the X-direction. In additional embodiments, the resist patterning material 219 is formed and patterned to cover multiple discrete portions of the second liner material 218, each discrete covered portion of the second liner material 218 being above a respective step 212 of the staircase structure 210.

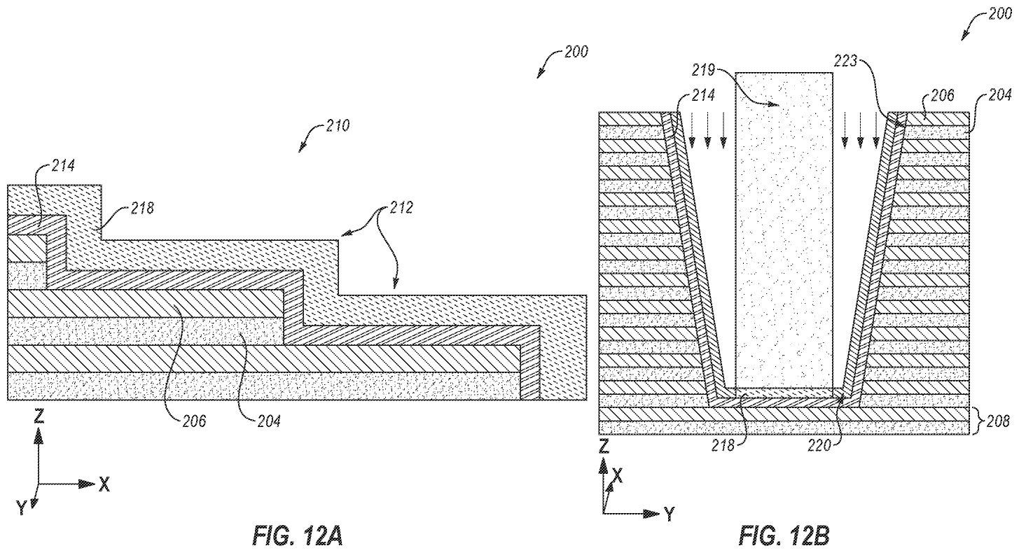

Referring next to FIGS. 12A and 12B, the exposed portions of second liner material 218 disposed on the first liner material 214 disposed over (e.g., lining) sidewalls 223 of the preliminary stack structure 202 (e.g., the vertically extending portions of the second liner material 218) may be doped (e.g., impregnated, implanted) with one or more dopants (e.g., chemical species) to form a doped second liner material 220. Furthermore, in some embodiments, only the exposed portions of the second liner material 218 are doped, and covered portions of the second liner material 218 remain undoped (e.g., free of the one or more dopants), as depicted in FIGS. 12A and 12B. For example, horizontally extending portions of the second liner material 218 disposed over the steps 212 of the staircase structure 210 and covered by the resist patterning material 219 may remain undoped.

Thicknesses (e.g., in the Z-direction and/or the Y-direction) of the dopant(s) (e.g., a thickness of the doped second liner material 220) may be at least substantially equal to a thickness of the second liner material 218. In other words, at least substantially an entire thickness of the exposed portions of the second liner material 218 may be doped with the dopant.

The dopant(s) of the doped second liner material 220 may comprise material(s) promoting or facilitating selective removal of doped second liner material 220 relative to the undoped portion of the second liner material 218 and/or the first liner material 214. Depending on a material composition of the second liner material 218, the dopant(s) may, for example, comprise one or more of argon (Ar), germanium (Ge), phosphorus (P), arsenic (As), antimony (Sb), bismuth (Bi), aluminum (Al) and/or gallium (Ga)), nitrogen (N), oxygen (O), fluorine (F), chlorine (Cl), bromine (Br), hydrogen (H), deuterium (C H), helium (He), and neon (Ne). In some embodiments, such as some embodiments wherein the second liner material 218 comprises a dielectric nitride material (e.g., SiN_{y}), the dopant comprises argon (Ar) and/or germanium (Ge).

The doped second liner material 220 may exhibit a substantially homogeneous distribution of dopant(s) within the material thereof, or may exhibit a heterogeneous distribution of dopant(s) within the material thereof. In some embodiments, the doped second liner material 220 exhibits a substantially homogeneous distribution of dopant(s) within the material thereof, such that the doped second liner material 220 exhibits a substantially uniform (e.g., even, non-variable) distribution of the dopant(s) within the material thereof. For example, amounts (e.g., atomic concentrations) of the dopant(s) included in the doped second liner material 220 may not substantially vary throughout the vertical dimensions (e.g., in the Z-direction) of the doped second liner material 220. In additional embodiments, the doped second liner material 220 exhibits a substantially heterogeneous distribution of dopant(s) within the material thereof, such that the doped second liner material 220 exhibits a substantially non-uniform (e.g., non-even, variable) distribution of the dopant(s) within the material thereof. For example, amounts (e.g., atomic concentrations) of the dopant(s) included in the doped second liner material 220 may vary (e.g., increase, decrease) throughout a vertical dimension (e.g., in the Z-direction) of the doped second liner material 220.

The second liner material 218 may be doped with at least one dopant to form the doped second liner material 220 using conventional processes (e.g., conventional implantation processes, conventional diffusion processes), which are not described in detail herein. As a non-limiting example, one or more argon-containing species (e.g., argon atoms, argon-containing molecules, argon ions, argon-containing ions) may be implanted into the second liner material 218 to form the doped second liner material 220. As another non-limiting example, one or more germanium-containing species (e.g., germanium atoms, germanium-containing molecules, germanium ions, germanium-containing ions) may be implanted into the second liner material 218 to form the doped second liner material 220. As an additional non-limiting example, one or more arsenic-containing species (e.g., arsenic atoms, arsenic-containing molecules, arsenic ions, arsenic-containing ions) may be implanted into the second liner material 218 to form the doped second liner material 220. In some embodiments, following dopant implantation, an amount of dopant within at least the doped second liner material 220 is within a range of from about 1.0×10¹⁷ dopant atoms per cubic centimeter (cm³) to about 1.0×10²³ dopant atoms/cm³.

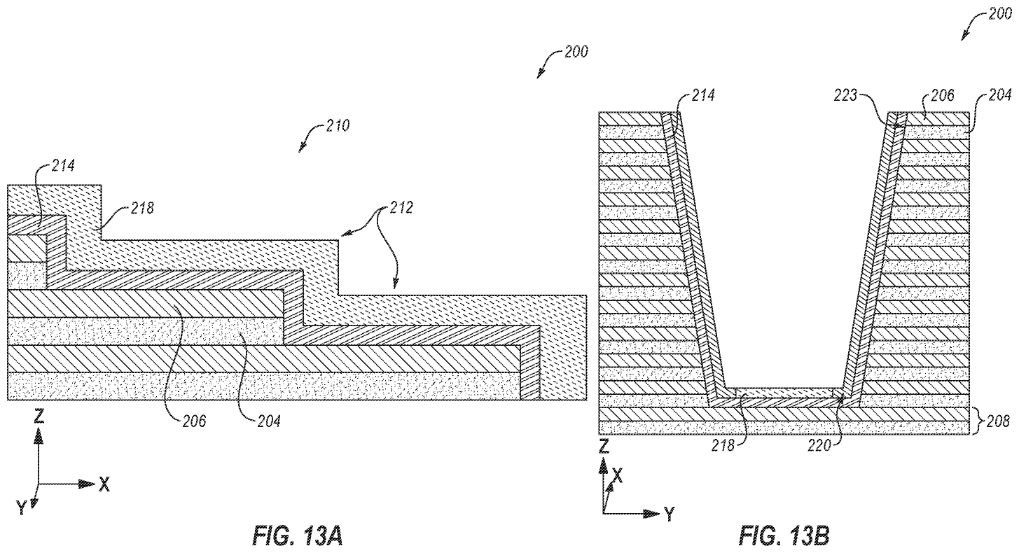

Referring next to FIGS. 13A and 13B, the resist patterning material 219 disposed over the preliminary stack structure 202 may be substantially removed. The resist patterning material 219 may be removed via conventional removal processes. For example, the removal processes may include one or more of dry etching, wet etching, or vapor etching. The dry etching may include one or more of RIE, deep RIE, plasma etching, reactive ion beam etching, or chemically assisted ion beam etching.

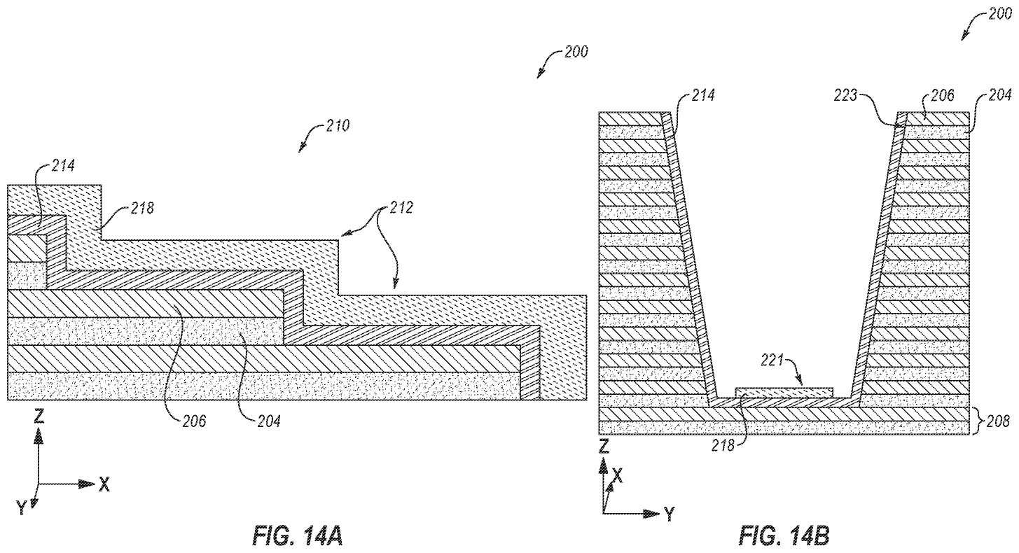

Referring next to FIGS. 14A and 14B, the doped second liner material 220 may be substantially, selectively removed. For example, the doped second liner material 220 disposed over the sidewalls 223 of the preliminary stack structure 202 horizontally bounding the steps 212 of the at least one staircase structure 210 and extending substantially vertically up from the first liner material 214 may be substantially removed to expose vertically and/or substantially vertically extending surfaces of the first liner material 214.

As shown in FIG. 14B, selective removal of the doped second liner material 220 disposed on the first liner material 214 disposed on the sidewalls 223 of the preliminary stack structure 202 horizontally bounding the at least one staircase structure 210 may define an etch stop structure 221 with the dopant-free second liner material 218. For example, selective removal of the doped second liner material 220 disposed on vertical surfaces of the first liner material 214 disposed on the sidewalls 223 of the preliminary stack structure 202 horizontally bounding the at least one staircase structure 210 may result in the dopant-free second liner material 218 disposed on horizontal surfaces of the first liner material 214 remaining and defining the etch stop structure 221. As a result, the portions of the first liner material 214 disposed on the sidewalls 223 of the preliminary stack structure 202 may be substantially free of the second liner material 218. As is discussed in greater detail below, removing the dopant-free portions of the second liner material 218 from the first liner material 214 disposed on the sidewalls 223 of the preliminary stack structure 202 horizontally bounding the at least one staircase structure 210 may reduce bending of latter formed contact structures (e.g., contact structures 148 (FIG. 10)).

In some embodiments, the etch stop structure 221 is spaced apart from the vertically extending portions of the first liner material 214 disposed on (e.g., lining) the sidewalls 223 of the preliminary stack structure 202 by at least some distance in the Y-direction. In additional embodiments, the etch stop structure 221 extends and contacts the vertically extending portions of the first liner material 214 disposed on (e.g., lining) the sidewalls 223 of the preliminary stack structure 202.

Referring still to FIGS. 14A and 14B, the doped second liner material 220 disposed on the sidewalls 223 of the preliminary stack structure 202 horizontally bounding the at least one staircase structure 210 may be removed by treating the second liner material 218 with at least one etchant (e.g., wet etchant). By way of non-limiting example, depending on the material composition of the second liner material 218, the etchant may comprise one or more of tetramethylammonium hydroxide (TMAH), hydrofluoric acid (HF), a buffered oxide etchant (BOE), or nitric acid (HNO₃). In additional embodiments, the material removal process includes treating the microelectronic device structure 200 with a solution including water and HF at a ratio within a range of from about 500:1 to about 100:1. The second liner material 218 may be exposed to the etchant using conventional processes (e.g., a spin-coating process, a spray-coating process, an immersion-coating process, a vapor-coating process, a soaking process, combinations thereof) and conventional processing equipment, which are not described in detail herein.

Subsequent to the process described in regard to FIGS. 11A-14B, the microelectronic device structure 200 may be further processed to form a microelectronic device of the disclosure. The further processing of the microelectronic device structure 200 may include any of the processes and acts previously described with reference to FIGS. 8-10.

Thus, in accordance with embodiments of the disclosure, a microelectronic device comprises a stack structure, a staircase structure, a first liner material, an etch stop structure, and conductive contact structures. The stack structure comprises vertically alternating conductive structures and insulative structures arranged in tiers. Each of the tiers individually comprises one of the conductive structures and one of the insulative structures. The stack structure includes sidewalls horizontally bounding the staircase structure and extending upward from the steps of the staircase structure. The staircase structure has steps comprising edges of at least some of the tiers of the stack structure. The first liner material is on the steps of the staircase structure and the sidewalls of the stack structure. The first liner material includes horizontally extending portions on the steps of the staircase structure and vertically extending portions on the sidewalls of the stack structure. The etch stop structure extends continuously on of the first liner material in a first horizontal direction and has a smaller width than the steps in a second horizontal direction orthogonal to the first horizontal direction. The conductive contact structures extend through the etch stop structure and the first liner material and to the conductive structures of the stack structure.

Furthermore, in accordance with embodiments of the disclosure, a method of forming a microelectronic device comprises forming a microelectronic device structure comprising a stack structure comprising a vertically alternating sequence of insulative material and sacrificial material arranged in tiers, and a staircase structure having steps comprising edges of at least some of the tiers of the stack structure, the stack structure comprising sidewalls horizontally bounding the staircase structure and extending upward from the steps of the staircase structure. A first liner material is formed on the steps of the staircase structure and the sidewalls of the stack structure. A second liner material is formed over the first liner material. A resist material is formed to cover at least one portion of the second liner material. The method further includes patterning the resist material to cover at least one portion of the second liner material, doping at least one portion of the second liner material with a dopant, removing the resist material, selectively removing a doped portion of the second liner material or a dopant-free portion of the second liner material while leaving the other of the doped portion of the second liner material or the dopant-free portion of the second liner material, a remaining portion of the second liner material forming an etch stop structure over each step of the staircase structure, at least partially replacing the sacrificial material of the tiers of the stack structure with conductive material, forming contact openings through the etch stop structure and the first liner material over each of the steps of the staircase structure, and forming conductive contact structures vertically extending through the etch stop structure and first liner material and to portions of the conductive material at the steps of the staircase structure, the conductive contact structures being substantially horizontally surrounded by the etch stop structure.

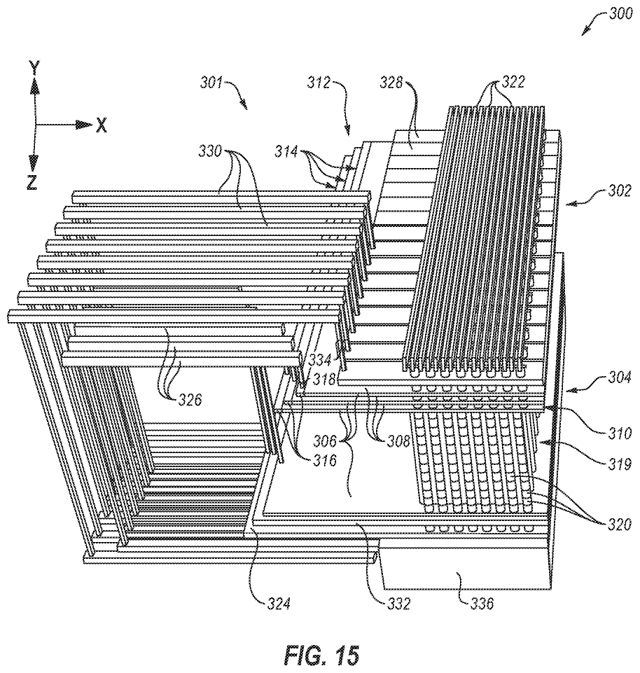

Microelectronic device structures (e.g., the microelectronic device structure 100 previously described with reference to FIG. 10; the microelectronic device structure 200 previously described with reference to FIGS. 14A and 14B) of the disclosure may be included in microelectronic devices of the disclosure. For example, FIG. 15 illustrates a partial cutaway perspective view of a portion of a microelectronic device 300 (e.g., a memory device, such as a 3D NAND Flash memory device) including a microelectronic device structure 302. The microelectronic device structure 302 may be substantially similar to one of the microelectronic device structures 100, 200 previously described with reference to FIG. 10 and FIGS. 14A and 14B. In some embodiments, the microelectronic device structure 302 is formed through processes previously described with reference to FIGS. 1A through 10. In additional embodiments, the microelectronic device structure 302 is formed through processes previously described with reference to FIGS. 11A through 14B, in conjunction with the processes previously described with reference to FIGS. 8 through 10.

As shown in FIG. 15, the microelectronic device structure 302 may include a stack structure 304 including a vertically alternating (e.g., in the Z-direction) sequence of conductive structures 306 and insulative structures 308 arranged in tiers 310; a staircase structure 312 having steps 314 defined by edges (e.g., horizontal ends in the X-direction) of the tiers 310; composite pad structures 316 on portions of the tiers 310 of the stack structure 304 at the steps 314 of the staircase structure 312; and conductive contact structures 318 extending through the composite pad structures 316 and contacting (e.g., physically contacting, electrically contacting) to the conductive structures 306 of the tiers 310 of the stack structure 304 at the steps 314 of the staircase structure 312. The stack structure 304, the conductive structures 306, the insulative structures 308, the tiers 310, the staircase structure 312, the steps 314, the composite pad structures 316, and the conductive contact structures 318 may respectively be substantially similar to the stack structure 138, the conductive structures 140, the insulative structures 141, the tiers 142, the staircase structure 110, the steps 112, the horizontally, and the contact structures 148 previously described with reference to FIG. 10 (and the corresponding features of the microelectronic device structure 200 previously described with reference to FIGS. 14A and 14B). The microelectronic device 300 also includes additional features (e.g., structures, devices) operatively associated with the microelectronic device structure 302, as described in further detail below.

The microelectronic device 300 may further include vertical strings 319 of memory cells 320 coupled to each other in series, digit line structures 322 (e.g., bit line structures), a source structure 324, access line routing structures 326, first select gates 328 (e.g., upper select gates, drain select gates (SGDs)), select line routing structures 330, second select gates 332 (e.g., lower select gates, source select gates (SGSs)), and additional contact structures 334. The vertical strings 319 of memory cells 320 extend vertically and orthogonal to conductive lines and tiers (e.g., the digit line structures 322, the source structure 324, the tiers 310 of the stack structure 304, the access line routing structures 326, the first select gates 328, the select line routing structures 330, the second select gates 332). In some embodiments, the memory cells 320 comprise so-called “MONOS” (metal-oxide-nitride-oxide-semiconductor) memory cells. In additional embodiments, the memory cells 320 comprise so-called “TANOS” (tantalum nitride-aluminum oxide-nitride-oxide-semiconductor) memory cells, or so-called “BETANOS” (band/barrier engineered TANOS) memory cells, each of which are subsets of MONOS memory cells. In further embodiments, the memory cells 320 comprise so-called “floating gate” memory cells. The conductive contact structures 318 and the additional contact structures 334 may electrically couple components to each other as shown (e.g., the select line routing structures 330 to the first select gates 328, the access line routing structures 326 to the tiers 310 of the stack structure 304 of the microelectronic device structure 302).

The microelectronic device 300 may also include a base structure 336 positioned vertically below the vertical strings 319 of memory cells 320. The base structure 336 may include at least one control logic region including control logic devices configured to control various operations of other features (e.g., the vertical strings 319 of memory cells 320) of the microelectronic device 300. As a non-limiting example, the control logic region of the base structure 336 may further include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., string drivers), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, MUX, error checking and correction (ECC) devices, self-refresh/wear leveling devices, and other chip/deck control circuitry. The control logic region of the base structure 336 may be coupled to the source structure 324, the access line routing structures 326, the select line routing structures 330, and the digit line structures 322. In some embodiments, the control logic region of the base structure 336 includes CMOS (complementary metal-oxide-semiconductor) circuitry. In such embodiments, the control logic region of the base structure 336 may be characterized as having a “CMOS under Array” (“CuA”) configuration.

Thus, in accordance with embodiments of the disclosure, a memory device comprises a stack structure, a staircase structure, a liner material, an etch stop structure, conductive contact structures, barrier structures, digit line structures, a source structure, strings of memory cells, access line routing structures, and a control logic circuitry. The stack structure comprises tiers each comprising a conductive structure and an insulative structure vertically adjacent the conductive structure. The staircase structure has steps comprising edges of at least some of the tiers of the stack structure, the stack structure comprising sidewalls horizontally bounding the staircase structure and extending upward from the steps of the staircase structure. The liner material is on the steps of the staircase structure and partially defines horizontal boundaries of filled contact openings over each step of the staircase structure, the liner material comprising horizontally extending portions on the steps of the staircase structure and vertically extending portions on the sidewalls of the stack structure. The etch stop structure is at least partially covering the liner material and partially defining horizontal boundaries of the filled contact openings over each step of the staircase structure. The etch stop structure has a smaller horizontal dimension than the steps. The conductive contact structures are within the boundaries of the filled contact openings and vertically extend to portions of at least some of the conductive structures of the stack structure at the steps of the staircase structure. The digit line structures overlie the stack structure. The source structure underlies the stack structure. The strings of memory cells extend vertically through the stack structure and are coupled to the source structure and the digit line structures. The access line routing structures are coupled to the conductive contact structures. The control logic circuitry vertically underlies the source structure and is within horizontal boundaries of the array of vertically extending strings of memory cells. The control logic circuitry is electrically coupled to the source structure, the digit line structures, and the access line routing structures.

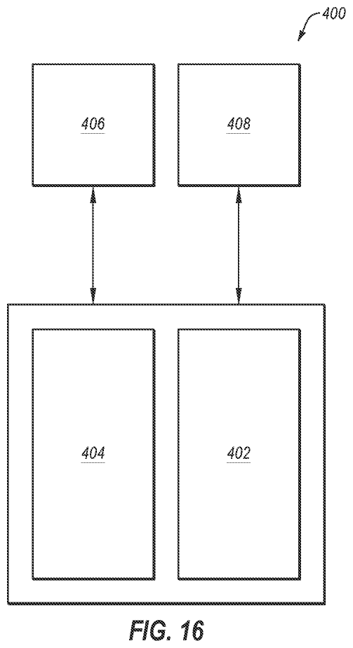

Microelectronic device structures (e.g., the microelectronic device structure 100 previously described with reference to FIG. 10; the microelectronic device structure 200 previously described with reference to FIGS. 14A and 14B) and microelectronic devices (e.g., the microelectronic device 300 previously described with reference to FIG. 15) in accordance with embodiments of the disclosure may be used in embodiments of electronic systems of the disclosure. For example, FIG. 16 is a block diagram of an illustrative electronic system 400 according to embodiments of disclosure. The electronic system 400 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 400 includes at least one memory device 402. The memory device 402 may comprise, for example, an embodiment of one or more of a microelectronic device structure and a microelectronic device previously described herein. The electronic system 400 may further include at least one electronic signal processor device 404 (often referred to as a “microprocessor”). The electronic signal processor device 404 may, optionally, include an embodiment of one or more of a microelectronic device structure and a microelectronic device previously described herein. While the memory device 402 and the electronic signal processor device 404 are depicted as two (2) separate devices in FIG. 16, in additional embodiments, a single (e.g., only one) memory/processor device having the functionalities of the memory device 402 and the electronic signal processor device 404 is included in the electronic system 400. In such embodiments, the memory/processor device may include one or more of a microelectronic device structure and a microelectronic device previously described herein. The electronic system 400 may further include one or more input devices 406 for inputting information into the electronic system 400 by a user, such as, for example, a mouse or other pointing device, a keyboard, a touchpad, a button, or a control panel. The electronic system 400 may further include one or more output devices 408 for outputting information (e.g., visual or audio output) to a user such as, for example, one or more of a monitor, a display, a printer, an audio output jack, and a speaker. In some embodiments, the input device 406 and the output device 408 may comprise a single touchscreen device that can be used both to input information to the electronic system 400 and to output visual information to a user. The input device 406 and the output device 408 may communicate electrically with one or more of the memory device 402 and the electronic signal processor device 404.

Thus, in accordance with embodiments of the disclosure, an electronic system comprises an input device, an output device, a processor device operably coupled to the input device and the output device, and a memory device operably coupled to the processor device. The memory device comprises a microelectronic device structure comprising a stack structure, a staircase structure, liner materials, and conductive contact structures. The stack structure comprises tiers each comprising a conductive structure, and an insulative structure vertically neighboring the conductive structure. The staircase structure is within the stack structure and has steps comprising edges of at least some of the tiers. The liner materials are overlying the staircase structure. One of the liner materials has a smaller width than the steps. The conductive contact structures extend through the liner materials and to at least some of the steps of the staircase structure.

The methods, structures (e.g., the microelectronic device structures 100, 200), devices (e.g., the microelectronic device 300), and systems (e.g., the electronic system 400) of the disclosure advantageously facilitate one or more of improved performance, reliability, and durability, lower costs, increased miniaturization of components, improved pattern quality, and greater packaging density as compared to conventional structures, conventional devices, and conventional systems. The methods and structures of the disclosure may alleviate problems related to the formation and processing of conventional microelectronic devices including stack structures having staircase structures at edges thereof. For example, the methods and structures of the disclosure may reduce the risk of undesirable damage (e.g., contact structure punch through) to conductive structures (e.g., the conductive structures 140) of stack structures (e.g., the stack structure 138) at steps (e.g., the steps 112) of staircase structures (e.g., the staircase structure 110), as well as undesirable current leakage and short circuits as compared to conventional methods and conventional structures.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalents.

What is claimed is:

1. A microelectronic device, comprising:
a stack structure comprising vertically alternating conductive structures and insulative structures arranged in tiers, each of the tiers individually comprising one of the conductive structures and one of the insulative structures;
a staircase structure having steps comprising edges of at least some of the tiers of the stack structure, the stack structure comprising sidewalls horizontally bounding the staircase structure and extending upward from the steps of the staircase structure;
a first liner material on the steps of the staircase structure and the sidewalls of the stack structure, the first liner material comprising horizontally extending portions on the steps of the staircase structure and vertically extending portions on the sidewalls of the stack structure;
an etch stop structure extending continuously on of the first liner material in a first horizontal direction and having a smaller width than the steps in a second horizontal direction orthogonal to the first horizontal direction; and
conductive contact structures extending through the etch stop structure and the first liner material and to the conductive structures of the stack structure.

2. The microelectronic device of claim 1, wherein the etch stop structure comprises a doped nitride material.

3. The microelectronic device of claim 2, wherein the doped nitride material comprises a carbon-doped nitride material.

4. The microelectronic device of claim 1, wherein the etch stop structure comprises a substantially undoped dielectric material, the substantially undoped dielectric material comprising a dopant-free nitride material.

5. The microelectronic device of claim 1, wherein each conductive contact structure is substantially horizontally surrounded by the etch stop structure.

6. The microelectronic device of claim 1, wherein the etch stop structure comprises a strip of material spanning multiple steps of the staircase structure in the first horizontal direction.

7. The microelectronic device of claim 1, wherein the etch stop structure is spaced apart from the vertically extending portions of the first liner material by at least some distance.

8. The microelectronic device of claim 1, wherein the first liner material comprises a dielectric oxide material.

9. The microelectronic device of claim 1, wherein only upper regions of the etch stop structure is doped with a chemical species.

10. A method of forming a microelectronic device, comprising:
forming a microelectronic device structure, the microelectronic device structure comprising:
a stack structure comprising a vertically alternating sequence of insulative material and sacrificial material arranged in tiers; and
a staircase structure having steps comprising edges of at least some of the tiers of the stack structure, the stack structure comprising sidewalls horizontally bounding the staircase structure and extending upward from the steps of the staircase structure;
forming a first liner material on the steps of the staircase structure and the sidewalls of the stack structure;
forming a second liner material over the first liner material;
forming resist material over the second liner material;
patterning the resist material to cover at least one portion of the second liner material;
doping at least one portion of the second liner material with a dopant;
removing the resist material;
selectively removing a doped portion of the second liner material or a dopant-free portion of the second liner material while leaving the other of the doped portion of the second liner material or the dopant-free portion of the second liner material, a remaining portion of the second liner material forming an etch stop structure over each step of the staircase structure;
at least partially replacing the sacrificial material of the tiers of the stack structure with conductive material;
forming contact openings through the etch stop structure and the first liner material over the steps of the staircase structure; and
forming conductive contact structures vertically extending through the etch stop structure and first liner material and to portions of the conductive material at the steps of the staircase structure, the conductive contact structures being substantially horizontally surrounded by the etch stop structure.

11. The method of claim 10, wherein doping at least one portion of the second liner material with a dopant comprises doping at least a portion of the second liner material with carbon (C).

12. The method of claim 10, wherein doping at least one portion of the second liner material with a dopant comprises doping at least a portion of the second liner material with argon (Ar).

13. The method of claim 10, wherein doping at least a portion of the second liner material with a dopant comprises doping a horizontally extending portion of the second liner material with the dopant, the horizontally extending portion of the second liner material horizontally overlapping at least one step of the staircase structure.

14. The method of claim 10, wherein doping at least a portion of the second liner material with a dopant comprises doping a vertically extending portion of the second liner material with the dopant, the vertically extending portion of the second liner material extending vertically over at least one sidewall of the stack structure.

15. The method of claim 10, wherein selectively removing a doped portion of the second liner material or a dopant-free portion of the second liner material while leaving the other of the doped portion of the second liner material or the dopant-free portion of the second liner material comprises selectively removing the doped portion of the second liner material.

16. The method of claim 10, wherein selectively removing a doped portion of the second liner material or a dopant-free portion of the second liner material while leaving the other of the doped portion of the second liner material or the dopant-free portion of the second liner material comprises selectively removing the dopant-free portion of the second liner material.

17. The method of claim 10, wherein patterning the resist material to cover at least one portion of the second liner material comprises patterning the resist material to cover a horizontally extending portion of the second liner material extending horizontally over at least one step of the staircase structure.

18. The method of claim 10, wherein patterning the resist material to cover at least one portion of the second liner material comprises patterning the resist material to cover at least substantially vertically extending portions of the second liner material extending vertically over the sidewalls of the stack structure.

19. The method of claim 10, wherein selectively removing a doped portion of the second liner material or a dopant-free portion of the second liner material while leaving the other of the doped portion of the second liner material or the dopant-free portion of the second liner material comprises forming an etch stop structure comprising a strip of material spanning multiple steps of the staircase structure.

20. The method of claim 10, wherein selectively removing a doped portion of the second liner material or a dopant-free portion of the second liner material while leaving the other of the doped portion of the second liner material or the dopant-free portion of the second liner material comprises forming an etch stop structure comprising discrete portions, each discrete portion being vertically above a respective step of the staircase structure.

21. A memory device, comprising:
a stack structure comprising tiers each comprising a conductive structure and an insulative structure vertically adjacent the conductive structure;
a staircase structure having steps comprising edges of at least some of the tiers of the stack structure, the stack structure comprising sidewalls horizontally bounding the staircase structure and extending upward from the steps of the staircase structure;
a liner material on the steps of the staircase structure and the sidewalls of the stack structure and partially defining horizontal boundaries of filled contact openings over each step of the staircase structure, the liner material comprising horizontally extending portions on the steps of the staircase structure and vertically extending portions on the sidewalls of the stack structure;
an etch stop structure at least partially covering the liner material and partially defining horizontal boundaries of the filled contact openings over each step of the staircase structure, the etch stop structure having a smaller horizontal dimension than the steps;
conductive contact structures within the horizontal boundaries of the filled contact openings and vertically extending to portions of at least some of the conductive structures of the stack structure at the steps of the staircase structure; and
strings of memory cells vertically extending through the stack structure.

22. The memory device of claim 21, wherein the etch stop structure comprises a doped nitride material.

23. The memory device of claim 22, wherein the doped nitride material comprises carbon.

24. The memory device of claim 21, wherein the etch stop structure extends continuously over the liner material in a first horizontal direction and has the smaller horizontal dimension than the steps in a second horizontal direction orthogonal to the first horizontal direction.

25. The memory device of claim 21, further comprising:
digit line structures overlying the stack structure and coupled to the strings of memory cells;
a source structure underlying the stack structure and coupled to the strings of memory cells;
access line routing structures coupled to the conductive contact structures; and
control logic circuitry vertically underlying the source structure and within horizontal boundaries of the strings of memory cells, the control logic circuitry coupled to the source structure, the digit line structures, and the access line routing structures.

26. An electronic system, comprising:
an input device;
an output device;
a processor device operably coupled to the input device and the output device; and
a memory device operably coupled to the processor device and comprising at least one microelectronic device structure comprising:
a stack structure comprising tiers each comprising:
a conductive structure; and
an insulative structure vertically neighboring the conductive structure;
a staircase structure within the stack structure and having steps comprising edges of at least some of the tiers;
liner materials overlying the staircase structure, one of the liner materials having a smaller width than the steps; and
conductive contact structures extending through the liner materials and to at least some of the steps of the staircase structure.
